(19) United States
(12) Patent Application Publication
(10) Pub. No.: US 2025/0029535 A1
(43) Pub. Date: Jan. 23, 2025

(54) DISPLAY MODULE INSPECTION DEVICE AND DISPLAY MODULE INSPECTION METHOD USING THE SAME

(71) Applicant: SAMSUNG DISPLAY CO., LTD., YONGIN-SI (KR)

(72) Inventors: HYEONSEO CHO, Yongin-si (KR); MIN-HONG KIM, Yongin-si (KR); SEUNGROK LEE, Yongin-si (KR)

(21) Appl. No.: 18/629,171

(22) Filed: Apr. 8, 2024

(30) Foreign Application Priority Data
Jul. 18, 2023 (KR) 10-2023-0093006

(51) Int. Cl. G09G 3/00; G01R 31/28

(52) U.S. Cl. CPC G09G 3/006; G01R 31/2806; G09G 2230/00

(57) ABSTRACT

Disclosed is a display module inspection device including a waveform generator configured to generate a first test signal and to transmit the first test signal to the display module, and a noise sensing unit configured to receive a second test signal from the display module, wherein the second test signal is indicative of a mutual capacitance between a plurality of sensing electrodes of the display module, wherein the noise sensing unit is configured to calculate a capacitance value based on the mutual capacitance and the first test signal, and wherein the capacitance value is indicative of noise.

### CROSS-REFERENCE TO RELATED APPLICATIONS

This application claims priority under 35 U.S.C. § 119 to Korean Patent Application No. 10-2023-0093006, filed on Jul. 18, 2023, in the Korean Intellectual Property Office, the disclosure of which is hereby incorporated by reference in its entirety.

### TECHNICAL FIELD

Embodiments of the present disclosure described herein relate to a display module inspection device, and more particularly, a display module inspection device capable of detecting interference between wires, and a display module inspecting method using the same.

### DISCUSSION OF RELATED ART

Display modules used in smartphones, televisions, monitors, and the like include various elements such as display layers and sensor layers. In a development and manufacturing process, a procedure of verifying interference characteristics between wires of the display module, which are respectively connected to the elements for transmitting and receiving signals, may be used to ensure the reliability of the elements.

### SUMMARY

Embodiments of the present disclosure provide a display module inspection device capable of reducing defects and measuring a degree of interference between wires of the display module, and a display module inspecting method using the same.

According to an embodiment, a display module inspection device includes a waveform generator configured to generate a first test signal and to transmit the first test signal to a display module, and a noise sensing unit configured to receive a second test signal from the display module, wherein the second test signal is indicative of a mutual capacitance between a plurality of sensing electrodes of the display module, wherein the noise sensing unit is configured to calculate a capacitance value based on the mutual capacitance and the first test signal, and wherein the capacitance value is indicative of noise.

The noise sensing unit may output test data including a respective capacitance value for each channel formed by the plurality of sensing electrodes of the display module.

The noise sensing unit may identify wires of the display module corresponding to a channel corresponding to the noise.

According to an embodiment, a display module inspection device includes an inspection board electrically connected to a display module, the display module including a sensor layer including a plurality of sensing electrodes, a waveform generator electrically connected to the inspection board and generating a first test signal and transmitting the first test signal to the display module, and a noise sensing unit electrically connected to the inspection board and receiving a second test signal from the display module. The second test signal is indicative of a mutual capacitance between the plurality of sensing electrodes.

The display module may further include a display layer, a data driver that drives the display layer, a sensor driver chip that drives the sensor layer, and a circuit board connected to the display layer.

The display module may further include a first wire disposed on the circuit board, electrically connected to the data driver, and a second wire disposed on the circuit board, electrically connected between the sensor driver chip and the sensor layer.

The waveform generator may transmit the first test signal to the first wire, and the noise sensing unit may receive the second test signal through the second wire.

At least a portion of the first wire may overlap at least a portion of the second wire.

The noise sensing unit may calculate a capacitance value based on the mutual capacitance.

The noise sensing unit may output test data including a respective capacitance value for each channel formed by the plurality of sensing electrodes.

The noise sensing unit may detect noise of the sensor layer.

The noise sensing unit may be configured to calculate a color dependent on a value of the capacitance.

The first test signal may be a simulated data signal.

The first test signal may include a 1-1st test signal having a first frequency and a 1-2nd test signal having a second frequency different from the first frequency.

According to an embodiment, a method of inspecting a display module includes mounting, on an inspection board, a display module including a display layer, a sensor layer including a plurality of sensing electrodes, a first wire electrically connected to the display layer, and a second wire electrically connected to the sensor layer, transmitting, by a waveform generator electrically connected to the inspection board, a first test signal to the first wire, receiving, by a noise sensing unit electrically connected to the inspection board, a second test signal from the second wire, the second test signal being indicative of mutual capacitance between the plurality of sensing electrodes, and detecting, by the noise sensing unit, noise of the display module based on the second test signal.

The detecting of the noise may include calculating, by the noise sensing unit, a capacitance value based on the mutual capacitance.

The detecting of the noise may include outputting, by the noise sensing unit, test data including the capacitance value for each channel formed by the plurality of sensing electrodes.

The detecting of the noise may include displaying the capacitance value in a color depending on the capacitance value.

The transmitting of the first test signal may include outputting a 1-1st test signal having a first frequency to the first wire and outputting a 1-2nd test signal having a second frequency different from the first frequency to the first wire.

The detecting of the noise may include detecting noise of the sensor layer upon determining that the capacitance value is different than an expect value given the first test signal transmitted to the first wire.

### BRIEF DESCRIPTION OF THE FIGURES

The above and other objects and features of the present disclosure will become apparent by describing in detail embodiments thereof with reference to the accompanying drawings.

FIG. 1 is a diagram illustrating a display module inspection device, according to an embodiment of the present disclosure.

FIG. 2 is a cross-sectional view of a display module according to an embodiment of the present disclosure.

FIG. 3 is a plan view showing a part of a display module, according to an embodiment of the present disclosure.

FIG. 4 is a plan view of a sensor layer, according to an embodiment of the present disclosure.

FIG. 5 is a plan view obtained by enlarging area AA′ of FIG. 3, according to an embodiment of the present disclosure.

FIG. 6 is an exploded perspective view illustrating area AA′ of FIG. 3, according to an embodiment of the present disclosure.

FIG. 7 is a flowchart illustrating a display module inspecting method, according to an embodiment of the present disclosure.

FIG. 8 illustrates test data, according to an embodiment of the present disclosure.

### DETAILED DESCRIPTION

In the specification, the expression that a first component (or region, layer, part, portion, etc.) is “on”, “connected with”, or “coupled with” a second component means that the first component may be directly on, connected with, or coupled with the second component, or a third component may be interposed between the first component and the second component. The expression that the first component is “directly disposed on”, “directly connected with”, or “directly coupled with” the second component means that no third component is interposed between the first component and the second component.

The same reference numerals refer to the same components. Also, in drawings, the thickness, ratio, and dimension of components may be exaggerated for effectiveness of description of technical contents. The expression “and/or” may include one or more combinations in which associated components are capable of defining.

Although the terms “first”, “second”, etc. may be used to describe various components, the components should not be construed as being limited by the terms. The terms may be used to distinguish one component from another component. For example, without departing from the scope and spirit of the present disclosure, a first component may be referred to as a second component, and similarly, the second component may be referred to as the first component. The articles “a,” “an,” and “the” are singular in that they have a single referent, but the use of the singular form in the specification should not preclude the presence of more than one referent.

Also, the terms “under”, “below”, “on”, “above”, etc. may be used to describe the correlation of components illustrated in drawings. The terms are relative and are described with reference to a direction indicated in the drawing.

It will be understood that the terms “include”, “comprise”, “have”, etc. specify the presence of features, numbers, steps, operations, elements, or components, described in the specification, or a combination thereof, not precluding the presence or additional possibility of one or more other features, numbers, steps, operations, elements, or components or a combination thereof.

Unless otherwise defined, all terms (including technical terms and scientific terms) used in the specification have the same meaning as commonly understood by one skilled in the art to which the present disclosure belongs. Furthermore, terms such as terms defined in the dictionaries commonly used should be interpreted as having a meaning consistent with the meaning in the context of the related technology, and should not be interpreted in ideal or overly formal meanings unless explicitly defined herein.

Hereinafter, embodiments of the present disclosure will be described with reference to accompanying drawings.

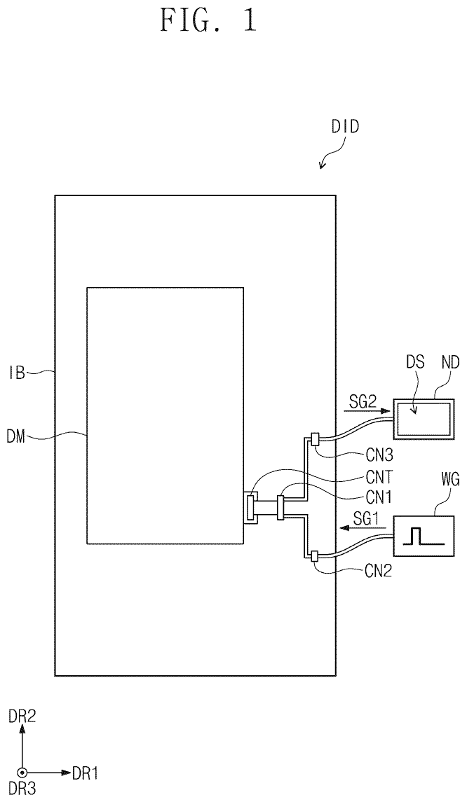

FIG. 1 is a diagram illustrating a display module inspection device, according to an embodiment of the present disclosure.

Referring to FIG. 1, a display module DM may be a device activated depending on an electrical signal. The display module DM may be implemented in various devices. For example, in addition to a large-sized electronic device such as televisions, monitors, or external billboards, the display module DM may be used in small and medium-sized electronic devices such as a personal computer, a notebook computer, a personal digital terminal, a car navigation unit, a game console, a portable electronic device, or a camera. These are non-limiting examples, and the display module DM may be implemented in various other electronic device(s) without departing from the concept of the present disclosure.

The display module DM may have a surface defined by a first direction DR1 and a second direction DR2 intersecting the first direction DR1. The display module DM may have a thickness in the third direction DR3. The third direction DR3 may intersect the first direction DR1 and the second direction DR2. For example, the third direction DR3 may be perpendicular to the surface defined by the first direction DR1 and the second direction DR2.

A display module inspection device DID may be used to inspect whether one or more functions of an inspection target operate. For example, the display module inspection device DID may quantitatively measure interference characteristics between wires, which may be respectively connected to elements of the display module DM to transmit and receive signals.

The display module inspection device DID may include an inspection board IB, a waveform generator WG, and a noise sensing unit ND.

The inspection board IB may be a board on which an inspection target may be placed. For example, the inspection target may include the display module DM. The inspection board IB may be electrically connected to the display module DM.

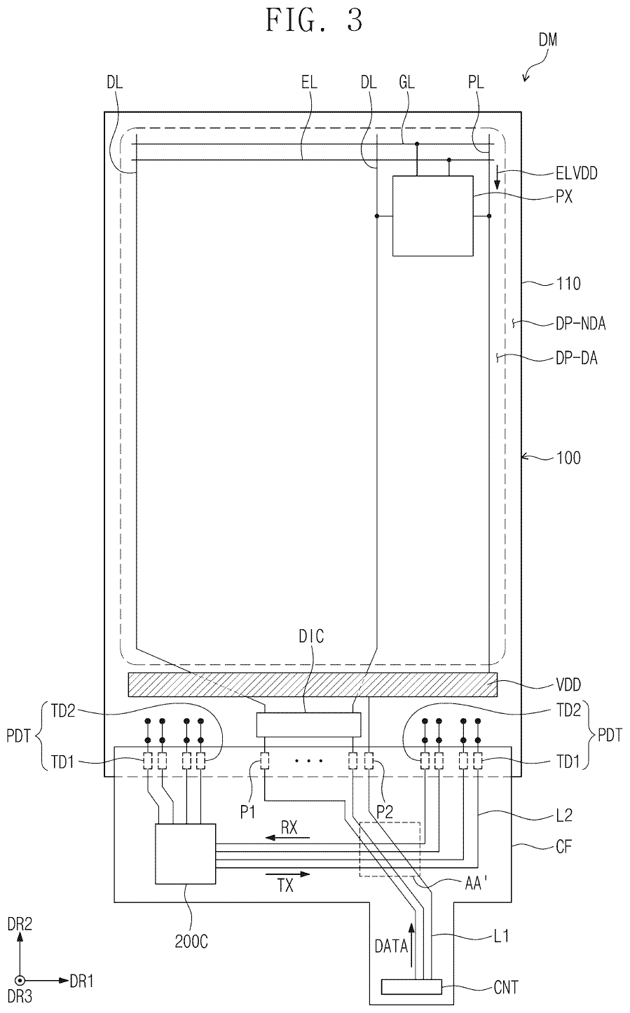

The inspection board IB may include a first connector CN1, a second connector CN2, and a third connector CN3. The display module DM may be connected to the first connector CN1 of the inspection board IB through a connector CNT (see also FIG. 3).

The first connector CN1 may deliver a signal to the display module DM or may receive a signal provided from the display module DM. The first connector CN1 may be electrically connected to one or more of the second connector CN2 or the third connector CN3.

The waveform generator WG may be electrically connected to the inspection board IB through the second connector CN2. The waveform generator WG may generate a first test signal SG1. For example, the waveform generator WG may include a function generator and an arbitrary waveform generator.

The waveform generator WG may transmit the first test signal SG1 to the display module DM. The waveform generator WG may transmit the first test signal SG1 to the display module DM through the second connector CN2 and the first connector CN1.

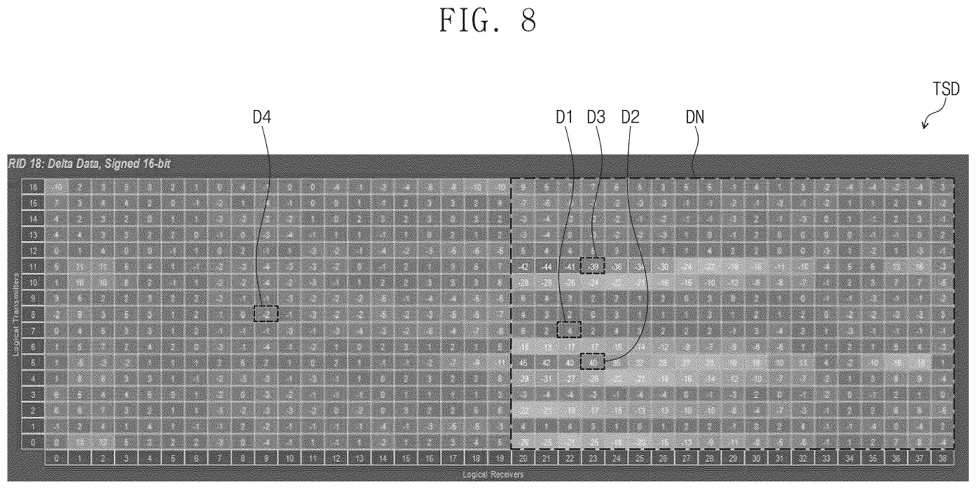

The noise sensing unit ND may be electrically connected to the inspection board IB through the third connector CN3. The noise sensing unit ND may receive a second test signal SG2 from the display module DM. The noise sensing unit ND may receive a second test signal SG2 from the display module DM through the first connector CN1 and the third connector CN3. The noise sensing unit ND may sense the noise of the display module DM based on the second test signal SG2. The noise sensing unit ND may display test data TSD (see FIG. 8) to an external user through a display unit DS.

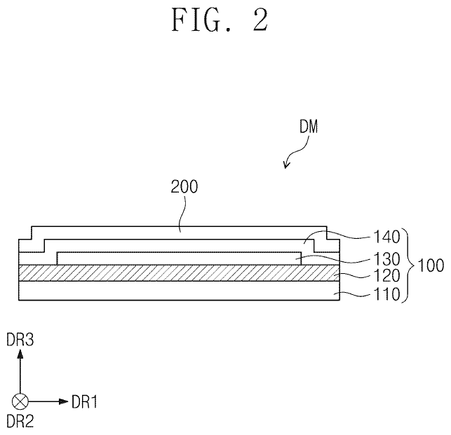

FIG. 2 is a cross-sectional view of a display module according to an embodiment of the present disclosure.

Referring to FIG. 2, the display module DM may include a display layer 100 and a sensor layer 200.

The display layer 100 may include a base layer 110, a circuit layer 120, a light emitting element layer 130, and an encapsulation layer 140.

The base layer 110 may be a member that provides a base surface on which the circuit layer 120 may be disposed. The base layer 110 may be a glass substrate, a metal substrate, a polymer substrate, or the like. However, the present disclosure is not limited thereto, and the base layer 110 may be an inorganic layer, an organic layer, or a composite material layer.

The base layer 110 may have a multi-layer structure. For example, the base layer 110 may include a first synthetic resin layer, a silicon oxide (SiOx) layer disposed on the first synthetic resin layer, an amorphous silicon (a-Si) layer disposed on the silicon oxide layer, and a second synthetic resin layer disposed on the amorphous silicon layer. The silicon oxide layer and the amorphous silicon layer may be referred to as a “base barrier layer”.

Each of the first synthetic resin layer and the second synthetic resin layer may include polyimide-based resin. Also, each of the first synthetic resin layer and the second synthetic resin layer may include at least one of acrylate-based resin, methacrylate-based resin, polyisoprene-based resin, vinyl-based resin, epoxy-based resin, urethane-based resin, cellulose-based resin, siloxane-based resin, polyamide-based resin, or perylene-based resin. By way of definition, “˜˜”—based resin in the specification means including the functional group of “˜˜”.

The circuit layer 120 may be disposed on the base layer 110. The circuit layer 120 may include an insulating layer, a semiconductor pattern, a conductive pattern, and a signal wire. The insulating layer, the semiconductor layer, and the conductive layer may be formed on the base layer 110 in a manner such as coating, evaporation, or the like. The insulating layer, the semiconductor layer, and the conductive layer may be selectively patterned by, for example, performing a photolithography process multiple times. The semiconductor pattern, the conductive pattern, and the signal wire included in the circuit layer 120 may be formed by the patterning process.

The light emitting element layer 130 may be disposed on the circuit layer 120. The light emitting element layer 130 may include a light emitting element. For example, the light emitting element layer 130 may include an organic light emitting material, a quantum dot, a quantum rod, a micro-LED (light emitting diode), or a nano-LED.

The encapsulation layer 140 may be disposed on the light emitting element layer 130. The encapsulation layer 140 may protect the light emitting element layer 130 from foreign substances such as moisture, oxygen, and dust particles.

The sensor layer 200 may be disposed on the display layer 100. The sensor layer 200 may sense an external input applied from the outside. The external input may be a user input. The user input may include various types of external inputs such as a portion of the user's body (e.g., a finger touch), light, heat, pens, pressure, or the like.

The sensor layer 200 may be formed on the display layer 100 through a successive process. In this case, the sensor layer 200 may be expressed as being directly disposed on the display layer 100. That is, no third component may be interposed between the sensor layer 200 and the display layer 100. For example, a separate adhesive member may not be interposed between the sensor layer 200 and the display layer 100. Alternatively, the sensor layer 200 may be coupled to the display layer 100 through an adhesive member. The adhesive member may include a common adhesive or a common sticking agent.

The display device DM may have a touch performance. The touch performance may be related to characteristics such as touch accuracy, repeatability, or latency. Touch performance is not limited to these examples, and other measurements of touch performance may be considered. According to an embodiment, one or more of these characteristics may be affected by noise.

Although not illustrated in drawings, the display module DM may further include an anti-reflection layer and/or an optical layer may be disposed on the sensor layer 200. The anti-reflection layer may reduce the reflectance of external light incident from the outside of the display module DM. The optical layer may improve the front luminance of the display module DM by controlling a direction of light incident from the display layer 100.

FIG. 3 is a plan view showing a part of a display module, according to an embodiment of the present disclosure.

Referring to FIG. 2 and FIG. 3, the display module DM may include the display layer 100, a power pattern VDD, a data driver DIC, a circuit board CF, a sensor driver chip 200C, a first wire L1, a second wire L2, and the connector CNT.

A display area DP-DA and a peripheral area DP-NDA adjacent to the display area DP-DA may be defined in the display layer 100. The display area DP-DA may be an area in which an image is displayed. A plurality of pixels PX may be positioned in the display area DP-DA. The peripheral area DP-NDA may be an area in which driving circuits or driving wires are disposed. The peripheral area DP-NDA may be disposed at a periphery of the display area DP-DA.

The display layer 100 may include the base layer 110, the plurality of pixels PX, a plurality of signal wires GL, DL, PL, and EL, the plurality of display pads P1 and P2, and a plurality of sensing pads PDT.

Each of the plurality of pixels PX may display a primary color or a mixed color. Different pixels of the plurality of pixels PX may display different colors (e.g., different primary colors). The primary color may include red, green, or blue. The mixed color may include various colors such as white, yellow, cyan, or magenta. However, the color displayed by each of the pixels PX is not limited thereto.

The plurality of signal wires GL, DL, PL, and EL may be disposed on the base layer 110. The plurality of signal wires GL, DL, PL, and EL may be connected to the plurality of pixels PX to deliver electrical signals to the plurality of pixels PX. The plurality of signal wires GL, DL, PL, and EL may include a plurality of scan wires GL, a plurality of data wires DL, a plurality of power lines PL, and a plurality of emission control wires EL. However, this is an example, and a configuration of the plurality of signal wires GL, DL, PL, and EL according to an embodiment of the present disclosure is not limited thereto. For example, the plurality of signal wires GL, DL, PL, and EL according to an embodiment of the present disclosure may further include an initialization voltage wire.

The power pattern VDD may be disposed in the peripheral area DP-NDA. The power pattern VDD may be connected to the plurality of power lines PL. Each of the plurality of pixels PX may receive a power supply voltage ELVDD provided by the power line PL.

The plurality of display pads P1 and P2 may be positioned in the peripheral area DP-NDA. The plurality of display pads P1 and P2 may include the first pad P1 and the second pad P2. The plurality of first pads P1 may be connected to the plurality of data wires DL, respectively. The second pad P2 may be connected to the power pattern VDD and may be electrically connected to the plurality of power lines PL. The display panel DP may provide the plurality of pixels PX with electrical signals from the plurality of display pads P1 and P2. The plurality of display pads P1 and P2 may further include pads for receiving other electrical signals in addition to the first pad P1 and the second pad P2. The plurality of display pads P1 and P2 may be variously configured and embodiments are not limited to any particular example described herein.

The data driver DIC may be disposed in the peripheral area of DP-NDA. The data driver DIC may be a timing control circuit in a chip form. The data driver DIC may output a grayscale voltage to the plurality of data wires DL in response to frame data of image data. The plurality of data wires DL may be electrically connected to the plurality of first pads P1 via the data driver DIC, respectively. However, this is an example and the data driver DIC may be variously implemented. For example, the data driver DIC according to an embodiment of the present disclosure may be disposed on a film separate from the display layer 100. In this example, the data driver DIC may be electrically connected to the plurality of display pads P1 and P2 through the film.

The plurality of sensing pads PDT may be positioned in the peripheral area DP-NDA. The plurality of sensing pads PDT may be electrically connected to a plurality of sensing electrodes of the sensor layer 200 (see FIG. 2). The plurality of sensing pads PDT may include a plurality of first sensing pads TD1 and a plurality of second sensing pads TD2.

The circuit board CF may be electrically connected to the plurality of display pads P1 and P2 and the plurality of sensing pads PDT.

The sensor driver chip 200C may be disposed on the circuit board CF. The sensor driver chip 200C may be electrically connected to the plurality of sensing pads PDT.

The first wire L1 may be electrically connected to the data driver DIC. For example, the first wire L1 may be connected between the connector CNT and the plurality of display pads P1 and P2. The first wire L1 may transmit and receive a data signal DATA. The data signal DATA may be referred to as a “MIPI signal”. The first wire L1 may be disposed on the circuit board CF. The first wire L1 may be referred to as a “MIPI wire”.

The second wire L2 may be electrically connected between the sensor layer 200 and the sensor driver chip 200C. For example, the second wire L2 may be connected between the sensor driver chip 200C and the plurality of sensing pads PDT. The second wire L2 may be provided with a touch transmission signal TX and a touch reception signal RX. The sensor driver chip 200C may transmit the touch transmission signal TX to the plurality of first sensing pads TD1 via the second wire L2. The sensor driver chip 200C may receive the touch reception signal RX from the plurality of first sensing pads TD1 via the second wire L2. The second wire L2 may be disposed on the circuit board CF.

As illustrated in FIG. 3, the first wire L1 may intersect with the second wire L2. The first wire L1 may intersect with the second wire L2 at the area AA′. That is, the touch transmission signal TX and/or the touch reception signal RX may be transmitted on the second wire L2 and the data signal DATA may be transmitted on the first wire L1 at substantially the same time. In some cases, the data signal DATA may interfere with the touch transmission signal TX and/or the touch reception signal RX. Interference may be detected as noise in the touch reception signal RX, which may be measured as an interference characteristic. It should be understood that interference may occur in an area of an intersection of lines, or may occur in another area. For example, interference may occur when different lines are in close proximity to each other.

The connector CNT may be electrically connected to each of the first wire L1 and the second wire L2. The connector CNT may be disposed on the circuit board CF. In the display device including the display module DM, the connector CNT may be connected to a host processor.

The host processor may include one or more of a central processing unit (CPU) or an application processor. The host processor may further include one or more of a graphic processing unit (GPU), a communication processor (CP), or an image signal processor (ISP). The host processor may further include a neural processing unit (NPU). The NPU may be a processor specialized in processing an artificial intelligence model, and the artificial intelligence model may be generated through machine learning. The artificial intelligence model may include a plurality of artificial neural network layers. The artificial neural network may be one of a deep neural network (DNN), a convolutional neural network (CNN), a recurrent neural network (RNN), a restricted Boltzmann machine (RBM), a deep belief network (DBN), a bidirectional recurrent deep neural network (BRDNN), or a deep Q-network, or a combination of two or more of the above-described networks, but may not be limited to the above-described example. In addition to a hardware structure, additionally or alternatively, the artificial intelligence model may include a software structure. At least two elements, such as two processing units, two processors, or a processing unit and a processor, which are described above, may be implemented as an integrated configuration (e.g., a single chip). Alternatively, each of the processing unit and the processor, which are described above, may be implemented as an independent configuration (e.g., a plurality of chips).

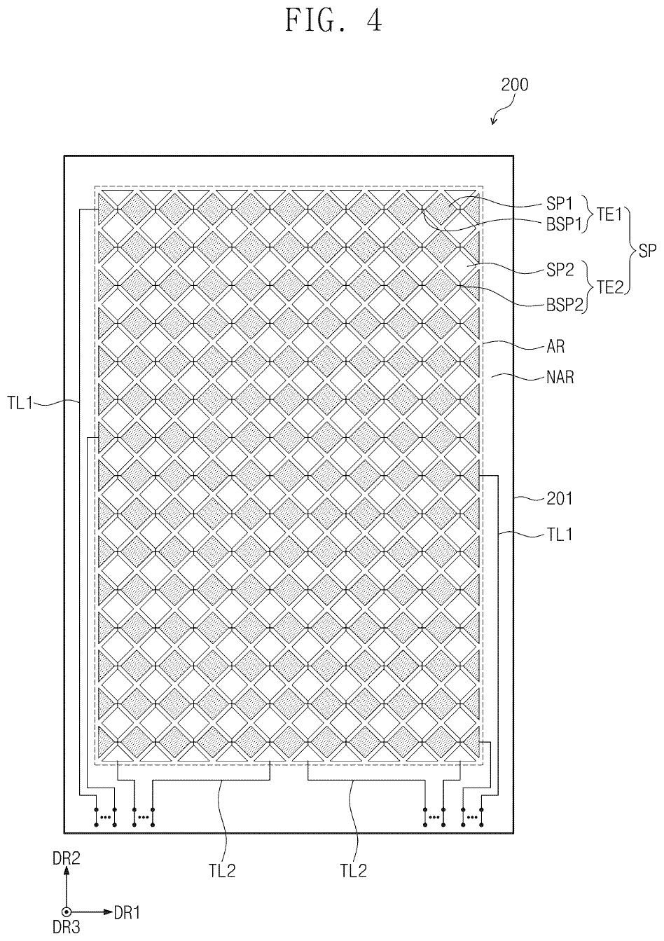

FIG. 4 is a plan view of a sensor layer, according to an embodiment of the present disclosure.

Referring to FIG. 3 and FIG. 4, the sensor layer 200 may include an active area AR and a peripheral area NAR adjacent to the active area AR. The peripheral area NAR may be disposed at a periphery of the active area AR. The active area AR may be activated according to an electrical signal. The active area AR may be an area in which an input is sensed. The active area AR may overlap the display area DP-DA of the display layer 100. The peripheral area NAR may overlap the peripheral area DP-NDA of the display layer 100. A portion of the active area AR may overlap the peripheral area DP-NDA of the display layer 100. Similarly, a portion of the peripheral area NAR may overlap the display area DP-DA of the display layer 100.

The sensor layer 200 may include a base layer 201, a plurality of sensing electrodes SP, and a plurality of sensing lines TL1 and TL2. The plurality of first sensing electrodes TE1 and the plurality of second sensing electrodes TE2 may be disposed in the active area AR, and the plurality of sensing lines TL1 and TL2 may be disposed in the peripheral area NAR.

A base layer 201 may be an inorganic layer including one of silicon nitride, silicon oxynitride, or silicon oxide. Alternatively, the base layer 201 may be an organic layer including an epoxy resin, an acrylate resin, or an imide-based resin. The base layer 201 may be directly formed on the display layer 100. Alternatively, an adhesive member may be disposed between the base layer 201 and the display layer 100. Accordingly, the base layer 201 and the display layer 100 may be coupled.

The plurality of sensing electrodes SP may include a plurality of first sensing electrodes TE1 and a plurality of second sensing electrodes TE2. An input sensing layer ISU (not illustrated) may obtain information about an external input through a change in capacitance between the plurality of first sensing electrodes TEL and the plurality of second sensing electrodes TE2.

Each of the plurality of first sensing electrodes TE1 may extend in the first direction DR1, and the plurality of first sensing electrodes TE1 may be arranged in the second direction DR2. For example, the plurality of first sensing electrodes TE1 may be arranged in rows extending in the first direction DR1. Each of the plurality of first sensing electrodes TE1 may include a plurality of first portions SP1 and a plurality of second portions BSP1. Each of the plurality of second portions BSP1 may electrically connect adjacent first portions SP1. For example, a second portion BSP1 may electrically connect two first portions SP1 adjacent to each other in the first direction DR1. The plurality of first portions SP1 and the plurality of second portions BSP1 may have a mesh structure. The plurality of first portions SP1 may be referred to as a “plurality of first sensing units SP1”. The plurality of second portions BSP1 may be referred to as a “plurality of first connection units BSP1”.

Each of the plurality of second sensing electrodes TE2 may extend in the second direction DR2, and the plurality of second sensing electrodes TE2 may be arranged in the first direction DR1. For example, the plurality of second sensing electrodes TE2 may be arranged in columns extending in the second direction DR2. Each of the plurality of second sensing electrodes TE2 may include a plurality of sensing patterns SP2 and a plurality of bridge patterns BSP2. Each of the plurality of bridge patterns BSP2 may electrically connect adjacent sensing patterns SP2. For example, a bridge pattern BSP2 may electrically connect two sensing patterns SP2 adjacent to each other in the first direction DR1. The plurality of sensing patterns SP2 may have a mesh structure. The plurality of sensing patterns SP2 may be referred to as a “plurality of second sensing units SP2”. The plurality of bridge patterns BSP2 may be referred to as a “plurality of second connection units BSP2”.

The plurality of second portions BSP1 may be disposed on a layer different from a layer on which the plurality of bridge patterns BSP2 are disposed. In a plan view, the plurality of bridge patterns BSP2 may intersect with the plurality of second portions BSP1. The plurality of second portions BSP1 may be intersect with, and be insulated from the plurality of bridge patterns BSP2.

The plurality of sensing lines TL1 and TL2 may include the plurality of first sensing lines TL1 and the plurality of second sensing lines TL2. The plurality of first sensing lines TL1 may be electrically connected to the plurality of first sensing electrodes TE1. For example, the plurality of first sensing lines TL1 may be electrically connected to the rows of the plurality of first sensing units SP1 extending in the first direction DR1. The plurality of second sensing lines TL2 may be electrically connected to the plurality of second sensing electrodes TE2, respectively. For example, the plurality of second sensing lines TL2 may be electrically connected to the columns of the plurality of second sensing units SP2 extending in the second direction DR2.

The plurality of first sensing lines TL1 may each be electrically connected to the plurality of first sensing pads TD1 through contact holes, respectively. The plurality of second sensing lines TL2 may each be electrically connected to the plurality of second sensing pads TD2 through contact holes, respectively.

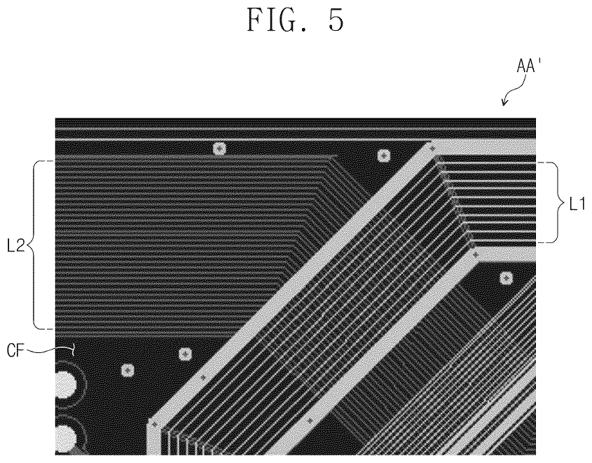

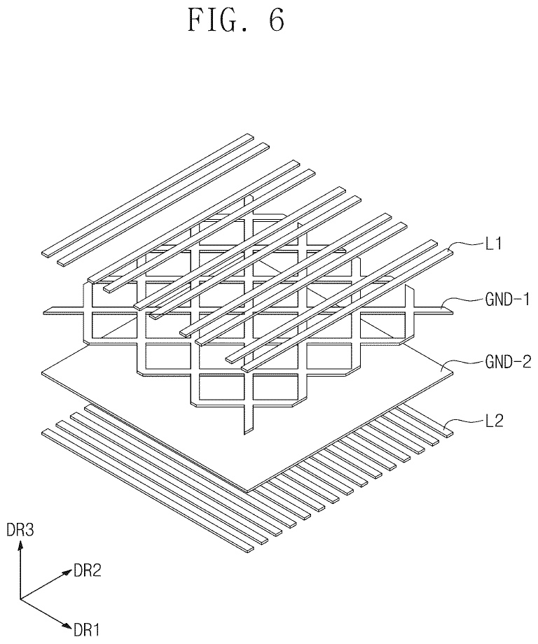

FIG. 5 is a plan view obtained by enlarging area AA′ of FIG. 3, according to an embodiment of the present disclosure. FIG. 6 is an exploded perspective view illustrating area AA′ of FIG. 3, according to an embodiment of the present disclosure.

Referring to FIG. 5 and FIG. 6, the first wire L1 and the second wire L2 may be disposed on the circuit board CF. For example, the second wire L2 may be disposed on the circuit board CF, and the first wire L1 may be disposed on the second wire L2. The first wire L1 and the second wire L2 may be spaced apart from each other in the third direction DR3. When viewed from above in a plan view, a portion of the first wire L1 may overlap a portion of the second wire L2.

The display module DM (see FIG. 3) may further include a first ground layer GND-1 and a second ground layer GND-2 (see FIG. 6). The first ground layer GND-1 and the second ground layer GND-2 may be further disposed on the circuit board CF. For example, the second wire L2 may be disposed on the circuit board CF; the second ground layer GND-2 may be disposed on the second wire L2; the first ground layer GND-1 may be disposed on the second ground layer GND-2; and the first wire L1 may be disposed on the first ground layer GND-1.

The first ground layer GND-1 may be interposed between the second ground layer GND-2 and the first wire L1. The first ground layer GND-1 may be placed to reduce or minimize interference between the first wire L1 and the second wire L2. The first ground layer GND-1 may have a mesh structure for impedance matching of the first wire L1. The first ground layer GND-1 is not limited to any particular structure, and the shape of the first ground layer GND-1 may be variously configured. According to an embodiment, the first ground layer GND-1 may be omitted.

The second ground layer GND-2 may be interposed between the first ground layer GND-1 and the second wire L2. The second ground layer GND-2 may be disposed to reduce or minimize interference between the first wire L1 and the second wire L2. The second ground layer GND-2 may have a solid plate structure. The second ground layer GND-2 is not limited to any particular structure, and the structure of the second ground layer GND-2 may be variously configured. According to an embodiment, the second ground layer GND-2 may be omitted.

When at least one of the first ground layer GND-1 and the second ground layer GND-2 is omitted, interference may be generated by an interference capacitor formed between the first wire L1 and the second wire L2 that overlap each other in a plan view. According to an embodiment of the present disclosure, the display module inspection device DID (see FIG. 1) may detect noise of the display module DM (see FIG. 1). The noise sensing unit ND (see FIG. 1) may quantitatively measure noise, which may be an interference characteristic. Accordingly, the first wire L1 and the second wire L2 associated with the noise and a decrease in touch performance occurring in the sensor layer 200 (see FIG. 2) may be determined by the noise sensing unit ND. Accordingly, a structure or arrangement of the first wire L1 and/or the second wire L2, which are disposed on the circuit board CF, may be redesigned to achieve an improved structure, which may reduce or eliminate the noise. Accordingly, it may be possible to provide the display module inspection device DID (see FIG. 1) with an improved capability to reliably inspect a display module DM, and a method for inspecting the display module DM (see FIG. 1) by using the same.

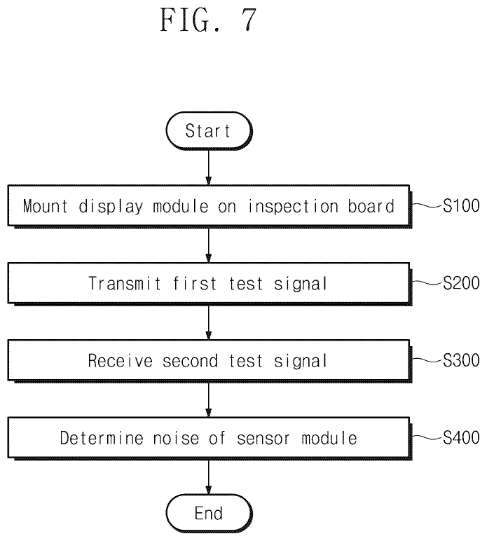

FIG. 7 is a flowchart illustrating a display module inspecting method, according to an embodiment of the present disclosure.

Referring to FIGS. 1 to 7, the display module DM may be mounted on the inspection board IB (S100). The display module DM may include the display layer 100, the sensor layer 200 including the plurality of sensing electrodes SP, the first wire L1 electrically connected to the display layer 100, and the second wire L2 electrically connected to the sensor layer 200.

The waveform generator WG may transmit the first test signal SG1 to the first wire L1 (S200).

The first test signal SG1 may be provided to the display module DM as a data signal DATA, and more particularly the MIPI signal. That is, the first test signal SG1 may be provided to the display module DM as a simulated data signal. The first test signal SG1 may include a 1-1^{st} test signal having a first frequency and a 1-2^{nd} test signal having a second frequency different from the first frequency. In other words, the waveform generator WG may generate the first test signal SG1 having different frequencies from each other.

According to an embodiment of the present disclosure, the display module inspection device DID may control the frequency of the first test signal SG1 provided to the display module DM. The display module inspection device DID may detect noise generated in response to a touch input depending on the frequency of an MIPI signal. The noise sensing unit ND (see FIG. 1) may quantitatively measure noise, which is an interference characteristic, under a condition. The noise may be detected as a deviation from an expected signal given some input, e.g., the frequency of the first test signal SG1. For example, noise may be detected on a channel corresponding to a sensing electrode as a capacitance value that is outside of an expected range of values given the frequency of the first test signal SG1 applied at the sensing electrode. Touch performance occurring in the sensor layer 200 (see FIG. 2) may be determined for each frequency of the MIPI signal based on the noise. Touch performance associated with noise may be determined and associated with the first wire L1 and the second wire L2. Accordingly, a structure or arrangement of the first wire L1 and the second wire L2, which are disposed on the circuit board CF, may be improved to lessen or eliminate the noise. Accordingly, it may be possible to provide the display module inspection device DID (see FIG. 1) with an improved capability to reliably inspect a display module DM, and a method for inspecting the display module DM (see FIG. 1) by using the same.

The noise sensing unit ND may receive the second test signal SG2 from the second wire L2 (S300). The second test signal SG2 may be influenced by the mutual capacitance between the plurality of sensing electrodes SP.

The noise sensing unit ND may detect the noise of the sensor layer 200 based on the second test signal SG2 (S400). The noise sensing unit ND may calculate a capacitance value based on the mutual capacitance. The noise sensing unit ND may output test data TSD (see FIG. 8) based on the capacitance value.

Furthermore, according to an embodiment of the present disclosure, the display module inspection device DID may detect noise of the display module DM. The noise sensing unit ND may quantitatively measure noise, which is an interference characteristic, and may provide the measured result as the test data TSD (see FIG. 8). A decrease in touch performance in the sensor layer 200 may be determined based on the measured noise and the test data TSD. The first wire L1 and the second wire L2 may be identified based on the channel associated with the noise. Accordingly, a structure of the first wire L1 and/or the second wire L2, which are disposed on the circuit board CF, may be improved. For example, the test data TSD may be reviewed, and the structure of the first wire L1 and/or the second wire L2 may be updated in newly designed display module. Accordingly, it is possible to provide a display module inspection device capable of measuring the degree of interference between wires, identifying wires that may contribute to the generation of interference, and a method of inspecting the display module DM by using the same.

FIG. 8 illustrates test data, according to an embodiment of the present disclosure.

Referring to FIGS. 1 to 8, the noise sensing unit ND may output the test data TSD. The test data TSD may include capacitance values D1, D2, D3, and D4 for each channel formed by the plurality of sensing electrodes SP.

A horizontal axis of the test data TSD may represent the plurality of first sensing electrodes TE1. A vertical axis of the test data TSD may represent the plurality of second sensing electrodes TE2. However, the present disclosure is not limited to any particular configuration of the test data TSD. For example, targets of the horizontal axis and the vertical axis of the test data TSD according to an embodiment of the present disclosure may be changed.

The test data TSD may be displayed and indicate data for a plurality of channels formed between the plurality of first sensing electrodes TE1 and the plurality of second sensing electrodes TE2.

The capacitance values D1, D2, D3, and D4 measured by the noise sensing unit ND may be displayed to respectively correspond to a plurality of channels. The capacitance values D1, D2, D3, and D4 may be disposed among first capacitance values shown on a right portion of the test data TSD, and second capacitance values shown on a left portion of the test data TSD.

The first capacitance values include values D1, D2, and D3 measured at the sensing electrodes, which are connected to the second wire L2 overlapping the first wire L1, from among the plurality of sensing electrodes SP may be displayed in a noise area DN at the right portion of the test data TSD. The first capacitance values may include the 1-1st capacitance value D1, the 1-2nd capacitance value D2, and a 1-3rd capacitance value D3. The 1-1st capacitance value D1 may be a capacitance value indicative of a normal operation, and the 1-2nd capacitance value D2 and the 1-3rd capacitance value D3 may be capacitance values indicative of noise. For example, the capacitance value of the noise area DN may be less than −20 or greater than 20.

The second capacitance values include value D4 measured at the sensing electrodes connected to the second wire L2, which do not overlap the first wire L1, from among the plurality of sensing electrodes SP. The second capacitance values may be displayed in a safe area at the left portion of the test data TSD. For example, the capacitance value of the safe area may be −20 to 20.

The sum of absolute values of the first capacitance values including values D1, D2, and D3 at the right portion of the test data TSD may be greater than the sum of absolute values of the second capacitance values including value D4 at the left portion of the test data TSD. That is, a difference between the first capacitance values and the second capacitance values may indicate an overall level of noise. The overall level of noise may be attributed to the second wire L2 overlapping the first wire L1.

When the first test signal SG1 indicates a noise signal due to the interference capacitance formed between the first wire L1 and the second wire L2 in the noise area DN at the right portion of the test data TSD, the absolute value of each of the 1-2nd capacitance value D2 and the 1-3rd capacitance value D3 formed in channels of the corresponding sensing electrodes may be greater than the absolute value of the second capacitance value D4.

In the test data TSD, the capacitance values D1, D2, D3, and D4 may be displayed in different colors depending on capacitance values. Each of the 1-2nd capacitance value D2 and the 1-3rd capacitance value D3 may be displayed in different colors from the second capacitance value D4. For example, the 1-1st capacitance value D1 and the second capacitance value D4, which are normal, may be displayed in green; the 1-2nd capacitance value D2, indicating noise, may be displayed in red; and the 1-3rd capacitance value D3 may be displayed in blue.

According to an embodiment of the present disclosure, the noise sensing unit ND may display a capacitance value in different colors depending on the capacitance value. When the first test signal SG1 is applied to the first wire L1, noise may be generated in a signal carried by the second wire L2, and a channel having a high capacitance value due to the noise may be indicated by color in the test data TSD. Accordingly, a user may perceive that noise is present in the second test signal SG2 measured in the display module DM according to the colors and/or values in the test data TSD, and may examine the noise by changing a configuration of the display module, e.g., a routing of wires of the display module. Accordingly, it may be possible to provide the display module inspection device DID with an improved capability to reliably inspect a display module DM, and a method for inspecting the display module DM using the same.

Furthermore, according to an embodiment of the present disclosure, the display module inspection device DID may detect noise of the display module DM. The noise sensing unit ND may quantitatively measure noise, which is an interference characteristic, and may provide the measured result as the test data TSD. A decrease in touch performance capable occurring in the sensor layer 200 may be associated with certain channels and wires of the display module DM based on the noise. The first wire L1 and the second wire L2 may be identified based on the channel associated with the noise. Accordingly, the first wire L1 and the second wire L2, which are disposed on the circuit board CF, may be identified and changed to improve a structure of the display module DM. Accordingly, it may be possible to provide a display module inspection device DID capable of reducing defects and measuring the degree of interference between wires, and a method of inspecting the display module DM by using the same.

Although an embodiment of the present disclosure has been described for illustrative purposes, those skilled in the art will appreciate that various modifications, and substitutions are possible, without departing from the scope and spirit of the present disclosure as disclosed in the accompanying claims. Accordingly, the technical scope of the present disclosure is not limited to the detailed description of this specification, but should be defined by the claims.

As described above, a display module inspection device may detect noise in the display module. A noise sensing unit may quantitatively measure noise, which is an interference characteristic, and may provide the measured result as test data. Accordingly, a first wire and a second wire responsible for a decrease in touch performance may be identified based on the noise. Accordingly, the structure of the first wire and the second wire, which are disposed on a circuit board, may be changed to improve a structure of a display module. Accordingly, it may be possible to provide a display module inspection device capable of reducing defects and measuring the degree of interference between wires, and a display module inspecting method by using the same.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A display module inspection device comprising:
a waveform generator configured to generate a first test signal and to transmit the first test signal to a display module; and
a noise sensing unit configured to receive a second test signal from the display module,
wherein the second test signal is indicative of a mutual capacitance between a plurality of sensing electrodes of the display module,
wherein the noise sensing unit is configured to calculate a capacitance value based on the mutual capacitance and the first test signal,
and wherein the capacitance value is indicative of noise.

2. The display module inspection device of claim 1, wherein the noise sensing unit outputs test data including a respective capacitance value for each channel formed by the plurality of sensing electrodes of the display module.

3. The display module inspection device of claim 2, wherein the noise sensing unit identifies wires of the display module corresponding to a channel corresponding to the noise.

4. A display module inspection device comprising:
an inspection board electrically connected to a display module, the display module including a sensor layer including a plurality of sensing electrodes;
a waveform generator electrically connected to the inspection board and configured to generate a first test signal and to transmit the first test signal to the display module; and
a noise sensing unit electrically connected to the inspection board and configured to receive a second test signal from the display module,
wherein the second test signal is indicative of a mutual capacitance between the plurality of sensing electrodes.

5. The display module inspection device of claim 4, wherein the display module further includes:
a display layer;
a data driver configured to drive the display layer;
a sensor driver chip configured to drive the sensor layer; and
a circuit board connected to the display layer.

6. The display module inspection device of claim 5, wherein the display module further includes:
a first wire disposed on the circuit board, electrically connected to the data driver; and
a second wire disposed on the circuit board, electrically connected between the sensor driver chip and the sensor layer.

7. The display module inspection device of claim 6, wherein the waveform generator transmits the first test signal to the first wire, and
wherein the noise sensing unit receives the second test signal through the second wire.

8. The display module inspection device of claim 6, wherein at least a portion of the first wire overlaps at least a portion of the second wire.

9. The display module inspection device of claim 8, wherein the noise sensing unit calculates a capacitance value based on the mutual capacitance.

10. The display module inspection device of claim 9, wherein the noise sensing unit outputs test data including a respective capacitance value for each channel formed by the plurality of sensing electrodes.

11. The display module inspection device of claim 9, wherein the noise sensing unit detects noise of the sensor layer.

12. The display module inspection device of claim 9, wherein the noise sensing unit is configured to calculate a color dependent on a value of the capacitance value.

13. The display module inspection device of claim 4, wherein the first test signal is a simulated data signal.

14. The display module inspection device of claim 4, wherein the first test signal includes a 1-1st test signal having a first frequency and a 1-2nd test signal having a second frequency different from the first frequency.

15. A method of inspecting a display module, the method comprising:
mounting, on an inspection board, a display module including a display layer, a sensor layer including a plurality of sensing electrodes, a first wire electrically connected to the display layer, and a second wire electrically connected to the sensor layer;
transmitting, by a waveform generator electrically connected to the inspection board, a first test signal to the first wire;
receiving, by a noise sensing unit electrically connected to the inspection board, a second test signal from the second wire, the second test signal being indicative of mutual capacitance between the plurality of sensing electrodes; and
detecting, by the noise sensing unit, noise of the display module based on the second test signal.

16. The method of claim 15, wherein the detecting of the noise includes:
calculating, by the noise sensing unit, a capacitance value based on the mutual capacitance.

17. The method of claim 16, wherein the detecting of the noise further includes:
outputting, by the noise sensing unit, test data including the capacitance value for each channel formed by the plurality of sensing electrodes.

18. The method of claim 16, wherein the detecting of the noise further includes:
displaying the capacitance value in a color depending on the capacitance value.

19. The method of claim 15, wherein the transmitting of the first test signal includes:
outputting a 1-1st test signal having a first frequency to the first wire; and
outputting a 1-2nd test signal having a second frequency different from the first frequency to the first wire.

20. The method of claim 16, wherein the detecting of the noise includes:
detecting noise of the sensor layer upon determining that the capacitance value is different than an expect value given the first test signal transmitted to the first wire.
